(19) United States
(12) Patent Application Publication
(10) Pub. No.: US 2026/0047190 A1
(43) Pub. Date: Feb. 12, 2026

(54) SEMICONDUCTOR DEVICE AND METHOD OF MANUFACTURING THE SAME

(71) Applicant: Samsung Electronics Co., Ltd., Suwon-si (KR)

(72) Inventors: Younggwon Kim, Suwon-si (KR); Myunggil Kang, Suwon-si (KR); Wookhyun Kwon, Suwon-si (KR); Jongpil Kim, Suwon-si (KR); Jina Kim, Suwon-si (KR); Yunyeong Yi, Suwon-si (KR); Byounghak Hong, Suwon-si (KR)

(21) Appl. No.: 19/267,826

(22) Filed: Jul. 14, 2025

(30) Foreign Application Priority Data
Aug. 7, 2024 (KR) 10-2024-0105590

(51) Int. Cl. H10D 84/83; H10D 30/00; H10D 30/01; H10D 62/10; H10D 62/13; H10D 62/60; H10D 62/832; H10D 64/23; H10D 84/01

(52) U.S. Cl. CPC H10D 84/8312; H10D 30/502; H10D 62/102; H10D 62/116; H10D 62/151; H10D 62/60; H10D 62/832; H10D 64/256; H10D 84/8311; H10D 84/832; H10D 30/0191; H10D 84/013

(57) ABSTRACT

Semiconductor devices and manufacture methods thereof are provided. In one aspect, a semiconductor device includes a first transistor, where the first transistor includes first channel patterns stacked on a first active pattern with a first channel length and first source and drain patterns; and a second transistor, where the second transistor includes second channel patterns stacked on a second active pattern with a second channel length greater than the first channel length and second source and drain patterns. Each of the first source and drain patterns include a first high-resistivity bottom epitaxial layer, a first epitaxial layer, and a second epitaxial layer. Each of the second source and drain patterns includes a third epitaxial layer on the second active pattern and a fourth epitaxial layer. A bottom level of the first source and drain patterns is lower than a bottom level of the second source and drain patterns.

### CROSS-REFERENCE TO RELATED APPLICATION(S)

This application claims benefit of priority under 35 U.S.C. § 119 to Korean Patent Application No. 10-2024-0105590 filed on Aug. 7, 2024 in the Korean Intellectual Property Office, the disclosure of which is incorporated herein by reference in its entirety.

### BACKGROUND

As demand for high performance, high speed, and/or multi-functionality of a semiconductor device increases, integration density of a semiconductor device has increased. Also, a semiconductor device may be required to have high operating speeds and accuracy in operation.

Recently, in order to overcome limitations in operating characteristics due to a reduction of a size of a planar metal oxide semiconductor FET (MOSFET), a semiconductor device having a three-dimensional channel structure has been developed.

### SUMMARY

An example implementation of the present disclosure is to provide a semiconductor device having improved electrical properties and reliability.

An example implementation of the present disclosure is to provide a method of manufacturing a semiconductor device having improved electrical properties and reliability.

According to an example implementation of the present disclosure, a semiconductor device includes a substrate having a first active pattern and a second active pattern; a first transistor including first channel patterns stacked and spaced apart from each other on one region of the first active pattern and having a first channel length, a first gate structure on the first channel patterns, and first source/drain patterns disposed on both sides of the first gate structure; and a second transistor including second channel patterns stacked and spaced apart from each other on one region of the second active pattern and having a second channel length greater than the first channel length, a second gate structure on the second channel patterns, and second source/drain patterns disposed on both sides of the second gate structure, wherein each of the first source/drain patterns includes a first high-resistivity bottom epitaxial layer, a first epitaxial layer disposed on the first high-resistivity bottom epitaxial layer and connected to side surfaces of the first channel patterns, and a second epitaxial layer on the first epitaxial layer, wherein each of the second source/drain patterns includes a third epitaxial layer disposed on the second active pattern and connected to side surfaces of the second channel patterns, and a fourth epitaxial layer on the third epitaxial layer, and wherein a bottom level of the first source/drain patterns is lower than a bottom level of the second source/drain patterns, and the fourth epitaxial layer has a portion horizontally overlapping a lowermost channel pattern among the second channel patterns.

According to an example implementation of the present disclosure, a semiconductor device includes a substrate having a first region and a second region; a first transistor disposed on the first region of the substrate; and a second transistor disposed on a second region of the substrate, wherein the first transistor includes first channel patterns stacked and spaced apart from each other in a vertical direction on a first region of the substrate and having a first width in the first direction, a plurality of first gate structures spaced apart from each other in the first direction and surrounding the first channel patterns in a second direction intersecting the first direction, and a pair of first source/drain patterns disposed on both sides of each of the plurality of first gate structures in the second direction and connected to both side surfaces of the first channel patterns, respectively, wherein the second transistor includes second channel patterns stacked and spaced apart from each other in the vertical direction on the second region of the substrate and having a second width greater than the first width, a plurality of second gate structures spaced apart from each other in the first direction and surrounding the second channel patterns in the second direction, and a pair of second source/drain patterns disposed on both sides of each of the plurality of second gate structures in the second direction and connected to both side surfaces of the second channel patterns, respectively, wherein each of the pair of the first source/drain patterns includes a high-resistivity bottom epitaxial layer, a first epitaxial layer on the high-resistivity bottom epitaxial layer, and a second epitaxial layer on the first epitaxial layer, wherein each of the pair of second source/drain patterns includes a third epitaxial layer and a fourth epitaxial layer on the third epitaxial layer, and wherein a bottom level of the first source/drain patterns is lower than a bottom level of the second source/drain patterns, and the fourth epitaxial layer has a portion horizontally overlapping a lowermost channel pattern among the second channel patterns.

According to an example implementation of the present disclosure, a semiconductor device includes a substrate having a first active pattern and a second active pattern, each extending in a first direction; a first transistor including first channel patterns stacked and spaced apart from each other on one region of the first active pattern, a first gate structure extending in a second direction intersecting the first direction and surrounding each of the first channel patterns, and a pair of first source/drain patterns disposed on both sides of the first gate structure, respectively; and a circuit element including a semiconductor stack having first semiconductor patterns and second semiconductor patterns alternately stacked on one region of the second active pattern, a second gate structure extending in the second direction and intersecting the semiconductor stack, and a pair of epitaxial patterns disposed on both sides of the second gate structure, respectively, wherein a length of the semiconductor stack in the first direction is greater than a length of the first channel patterns in the first direction, and each of the first semiconductor patterns includes a semiconductor material the same as a semiconductor material of the first channel pattern, wherein each of the first source/drain patterns includes a high-resistivity bottom epitaxial layer, a first epitaxial layer disposed on the high-resistivity bottom epitaxial layer and connected to the side surfaces of the first channel patterns, and a second epitaxial layer on the first epitaxial layer, wherein each of the epitaxial patterns includes a third epitaxial layer disposed on the second active pattern and connected to side surfaces of the first and second semiconductor patterns, and a fourth epitaxial layer on the third epitaxial layer, and wherein a bottom level of the first source/drain patterns is lower than a bottom level of the epitaxial patterns, and the fourth epitaxial layer has a portion horizontally overlapping a lowermost second semiconductor pattern among the second semiconductor patterns.

According to an example implementation of the present disclosure, a method of manufacturing a semiconductor device includes preparing a first active pattern and a second active pattern extending on a first region and a second region of a substrate, respectively, and first and second fin-type structures disposed on the first and second active patterns, respectively, wherein the first and second fin-type structures include first semiconductor patterns and second semiconductor patterns stacked alternately; forming a first dummy gate structure crossing the first fin-type structure and a second dummy gate structure crossing the second fin-type structure, wherein a width of the second dummy gate structure is larger than a width of the first dummy gate structure; opening a first region of the substrate and forming a first mask covering the second region; forming a pair of first recesses removed from portions of the first fin-type structure to a portion region of the first active pattern on both sides of the first dummy gate structure; growing a first high-resistivity bottom epitaxial layer on a bottom of each of a pair of first recesses, and thereafter, growing a first epitaxial layer and a second epitaxial layer in order on an upper surface of the first high-resistivity bottom epitaxial layer and a sidewall of each of the first recesses; opening a second region of the substrate and forming a second mask covering the first region; forming a pair of second recesses removed from portions of the second fin-type structure to a portion region of the second active pattern on both sides of the second dummy gate structure; and growing a third epitaxial layer and a fourth epitaxial layer in order on a bottom of the pair of second recesses and on a sidewall of each of the second recesses.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan diagram illustrating an example semiconductor device;

FIG. 2 is a cross-sectional diagram illustrating a semiconductor device taken along lines I1-I1′ and I2-I2′ in FIG. 1;

FIG. 3 is a cross-sectional diagram illustrating a semiconductor device taken along lines II1-II1′ and II2-II2′ in FIG. 1;

FIG. 4 is a cross-sectional diagram illustrating a semiconductor device taken along lines III1-III1′ and III2-III2′ in FIG. 1;

FIG. 5 is a graph illustrating a change in recess depth depending on a distance between gate structures and a change in lower leakage current between elements depending on a recess depth;

FIG. 6 is cross-sectional diagrams illustrating an example semiconductor device;

FIG. 7 is cross-sectional diagrams illustrating a connection state of an example contact structure depending on a structure of a source/drain pattern;

FIG. 8 is a cross-sectional diagram illustrating an example semiconductor device (second transistor);

FIGS. 9A to 9D are perspective diagrams illustrating a portion of processes of a method of manufacturing an example semiconductor device;

FIGS. 10A to 10F are perspective diagrams illustrating the other portion of processes of a method of manufacturing an example semiconductor device;

FIG. 11 is a plan diagram illustrating an example semiconductor device;

FIG. 12 is cross-sectional diagrams illustrating a semiconductor device taken along lines I1-I1′, I2-I2′, and I3-I3′ in FIG. 11;

FIG. 13 is cross-sectional diagrams illustrating a semiconductor device taken along lines II1-II1′, II2-II2′, and II3-II3′ in FIG. 11; and

FIG. 14 is cross-sectional diagrams illustrating an example semiconductor device.

### DETAILED DESCRIPTION

Hereinafter, implementations of the present disclosure will be described as follows with reference to the accompanying drawings.

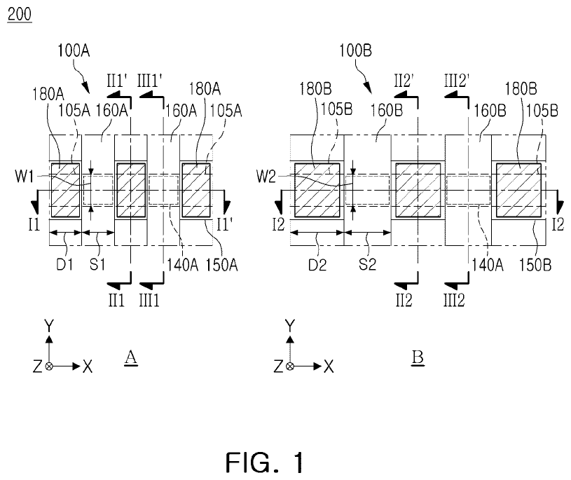

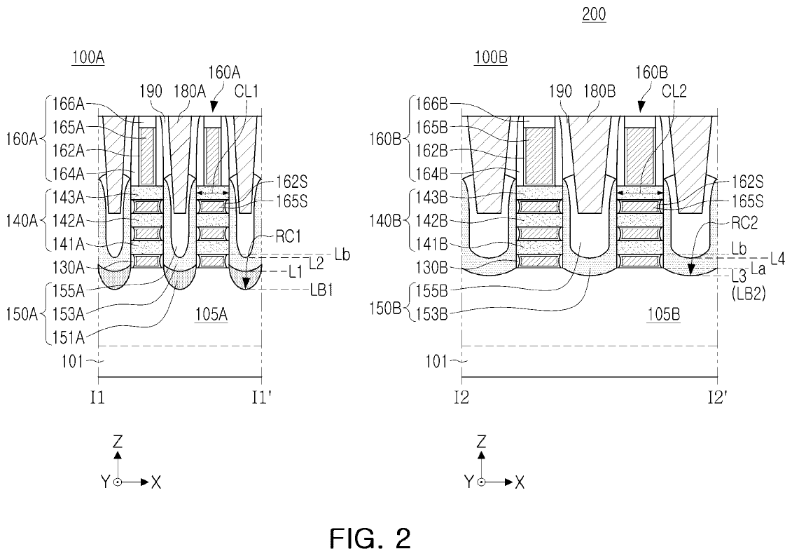

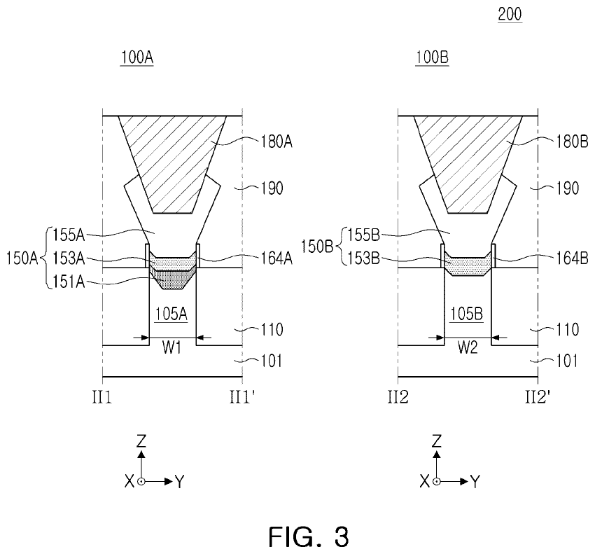

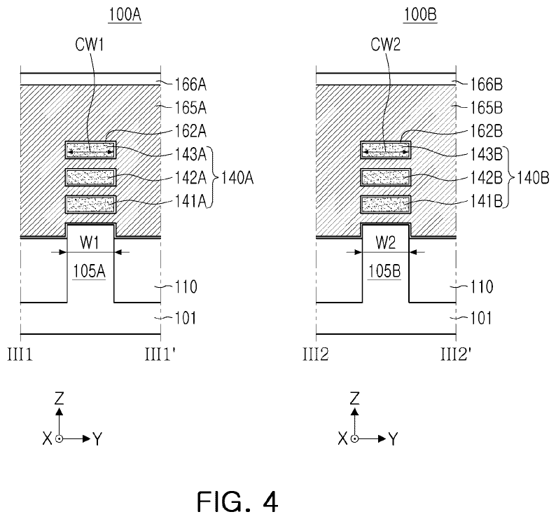

FIG. 1 is a plan diagram illustrating a semiconductor device according to an example implementation. FIG. 2 is a cross-sectional diagram illustrating a semiconductor device taken along lines I1-I1′ and I2-I2′ in FIG. 1. FIG. 3 is a cross-sectional diagram illustrating a semiconductor device taken along lines II1-II1′ and II2-II2′ in FIG. 1. FIG. 4 is a cross-sectional diagram illustrating a semiconductor device taken along lines III1-III1′ and III2-III2′ in FIG. 1.

Referring to FIGS. 1 to 4, a semiconductor device 200 according to the example implementation may include a substrate 101, a first transistor 100A disposed on a first region A of the substrate 101, and a second transistor 100B disposed on a second region B of the substrate 101.

In the example implementation, the first transistor 100A may be an element mainly included in a core device and may be referred to as a “short channel transistor” having a relatively short channel length, and the second transistor 100B may be an element for high voltage resistance and high reliability and may be referred to as a “long channel transistor” having a relatively long channel length.

Referring to FIGS. 1 and 2, a first transistor 100A may include a first active pattern 105A extending in a first direction (e.g., X-direction) on the first region A of the substrate 101, the first channel patterns 140A disposed on the first active pattern 105A, and the first gate structures 160A extending in a second direction (e.g., Y-direction) intersecting the first active pattern 105A. The first channel patterns 140A may be spaced apart from an upper surface of the substrate 101 in a vertical direction (e.g., Z-direction) on the first active pattern 105A. Also, the first transistor 100A may further include the first source/drain patterns 150A disposed on both sides of the first gate structure 160A and in contact with both side surfaces of the first channel patterns 140A, and first contact plugs 180A connected to the first source/drain patterns 150A.

Similarly, referring to FIGS. 1 and 2, the second transistor 100B may include second active patterns 105B extending in the first direction (e.g., X-direction) on the second region B of the substrate 101, second channel patterns 140B disposed on the second active pattern 105B, and second gate structures 160B extending in the second direction (e.g., Y-direction) intersecting the second active pattern 105B. The second channel

patterns 140B may be spaced apart from an upper surface of the substrate 101 in a direction perpendicular to the second active pattern 105B (e.g., Z-direction). Also, the second transistor 100B may further include second source/drain patterns 150B disposed on both sides of the second gate structure 160B and in contact with both side surfaces of the second channel patterns 140B, respectively, and second contact plugs 180B connected to the second source/drain patterns 150B.

Referring to FIG. 1, the first active pattern 105A may have a first width W1 in the second direction (e.g., Y-direction), and the second active pattern 105B may have a second width W2 in the second direction (e.g., Y-direction) substantially the same as the first width W1. In some example implementations, the first and second active patterns 105A and 105B may be structures obtained by dividing an active pattern into separate patterns. Similarly, widths of the first and second channel patterns 140A and 140B in the second direction (e.g., Y-direction) may be substantially the same.

In the example implementation, each of the first gate structures 160A may have a first width S1 in the first direction (e.g., X-direction) and may be arranged and spaced apart from each other by a first distance D1 in the first direction (e.g., X-direction). Each of the second gate structures 160B may have a second width S2 in the first direction (e.g., X-direction), which is greater than the first width S1, and may be arranged and spaced apart from each other by a second distance D2 in the first direction (e.g., X-direction), which is greater than the first distance D1. Lengths CL1 and CL2 of the first and second channel patterns 140A and 140B in the first direction (e.g., X-direction) may correspond to distances between first and second source/drain patterns 150A and 150B adjacent to each other, respectively, and may define the “channel lengths” of the first and second transistors 100A and 100B, respectively. In the example implementation, the lengths CL1 and CL2 of the first and second channel patterns 140A and 140B in the first direction (e.g., X-direction) may approximately correspond to the first width S1 of the first gate structures 160A and the second width S2 of the second gate structures 160B, respectively. The lengths CL1 and CL2 of the first and second channel patterns 140A and 140B in the first direction (e.g., X-direction) may have slightly different widths depending on levels of each pattern. In some example implementations, a lowermost channel patterns 141A and 141B may have a length close to the first width S1 and the second width S2, and the intermediate channel patterns 142A and 142B may have lengths less than the lengths of the uppermost channel patterns 143A and 143B and the lowermost channel patterns 141A and 141B.

By this arrangement, the first transistor 100A may be provided as a “short channel transistor” having a relatively short channel length, and the second transistor 100B may be provided as a “long channel transistor” having a relatively long channel length.

In the example implementation, the first and second active patterns 105A and 105B may have structures extending in the first direction (e.g., X-direction) and protruding in the third direction (e.g., Z-direction). Upper ends of the first and second active patterns 105A and 105B may protrude by a predetermined height from an upper surface of the element isolation layer 110. For example, the substrate 101 may be configured as a semiconductor substrate, such as a silicon substrate or a germanium substrate, or a silicon-on-insulator (SOI) substrate. The element isolation layer 110 may be disposed on the substrate 101 and may define the first and second active patterns 105A and 105B. The element isolation layer 110 may be disposed on the substrate 101 to cover a side surface of the active region 105 of the substrate 101. The element isolation layer 110 may include, for example, an oxide film, a nitride film, or a combination thereof. The element isolation layer 110 may be formed by a shallow trench isolation (STI) process. In some example implementations, the element isolation layer 110 may further include a region extending deeper into the substrate 101 (e.g., the deep trench isolation (DTI)). The element isolation layer 110 may be formed such that upper regions of the first and second active patterns 105A and 105B are exposed. In some example implementations, the element isolation layer 110 may have a curved upper surface having an increasing level toward the first and second active patterns 105A and 105B.

As described above, the first channel patterns 140A may be stacked and spaced apart from each other in the vertical direction (e.g., Z-direction) on the first active pattern 105A. Similarly, the second channel patterns 140B may be stacked and spaced apart from each other on the second active pattern 105B in the vertical direction (e.g., Z-direction). The first channel patterns 140A and the second channel pattern 140B may be formed by the same process. Thicknesses of the first channel patterns 141A, 142A, and 143A may be substantially the same as thicknesses of the second channel patterns 141B, 142B, and 143B at the same level, and channel patterns adjacent to each other at the same level may also be spaced apart from each other by substantially the same distance.

Each of the first channel patterns 140A and the second channel patterns 140B may include a semiconductor material which may provide a channel region. For example, the first and second channel patterns 140A and 140B may include at least one of silicon (Si), silicon germanium (SiGe), and germanium (Ge). The first and second channel patterns 140A and 140B may be formed of, for example, the same material as the substrate 101. In the example implementation, the number of each of the first and second channel patterns 140A and 140B may be three, but the number and the shape thereof may be varied.

The first and second channel patterns 140A and 140B may have widths CW1, CW2 the same as or similarly to those of the first and second active patterns 105A and 105B in the second direction (Y-direction), and may have widths the same as or similarly to widths of the first and second gate structures 160A and 160B in the first direction (X-direction). However, an example implementation thereof is not limited thereto, and in some example implementations, in each stack, widths of the channel patterns 140A and 140B may be different, but an example implementation thereof is not limited thereto.

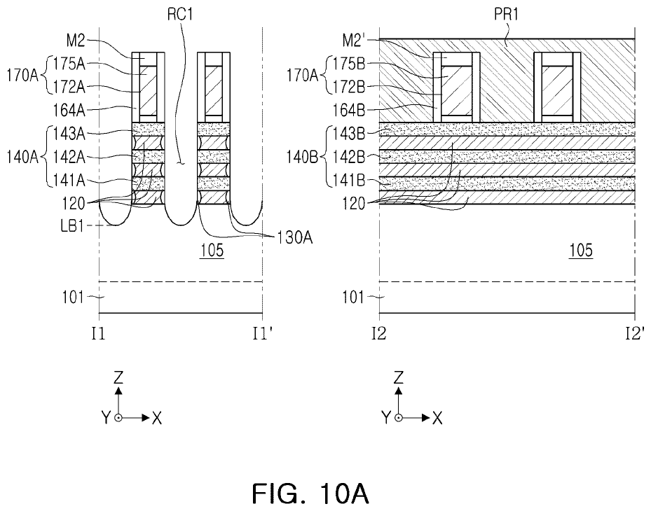

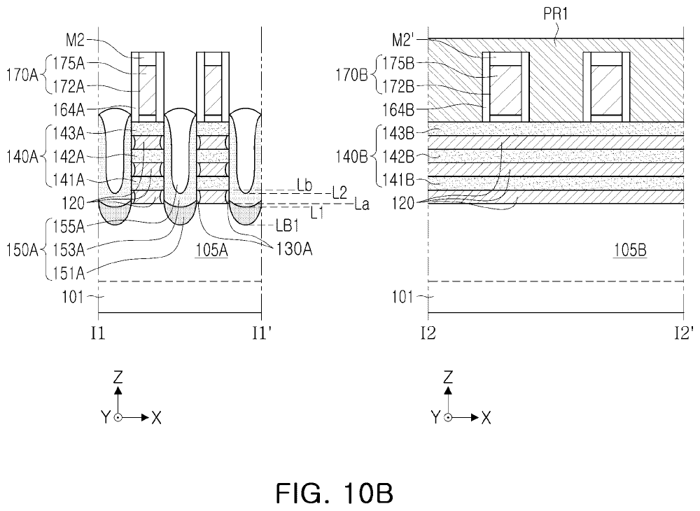

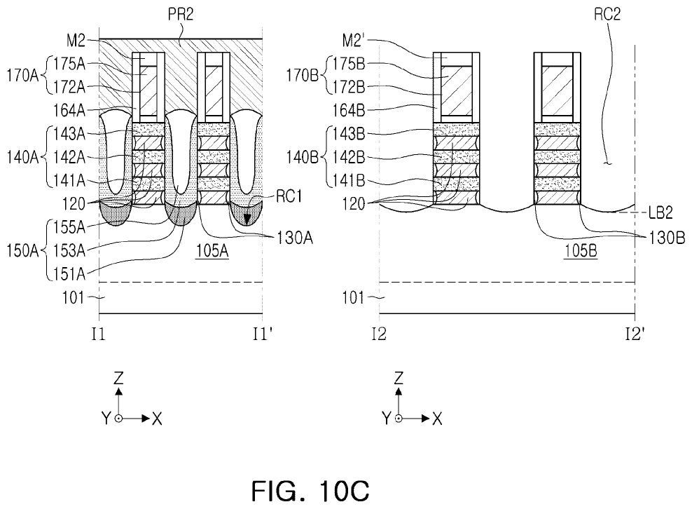

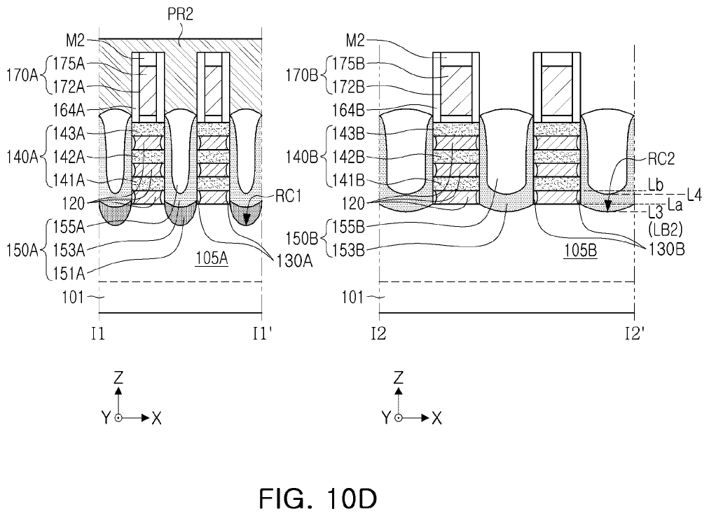

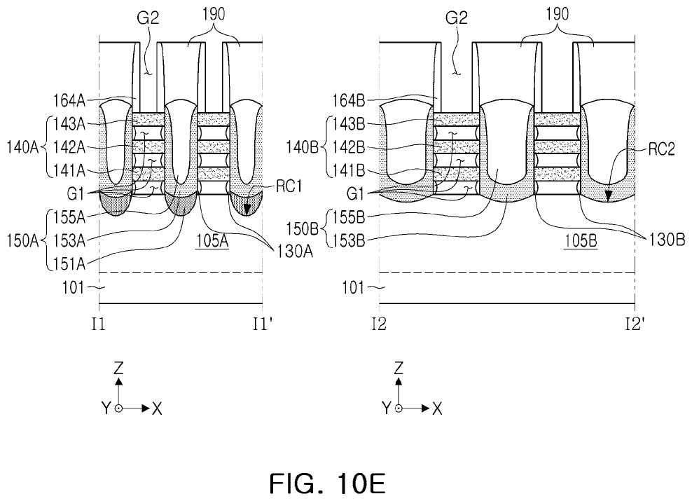

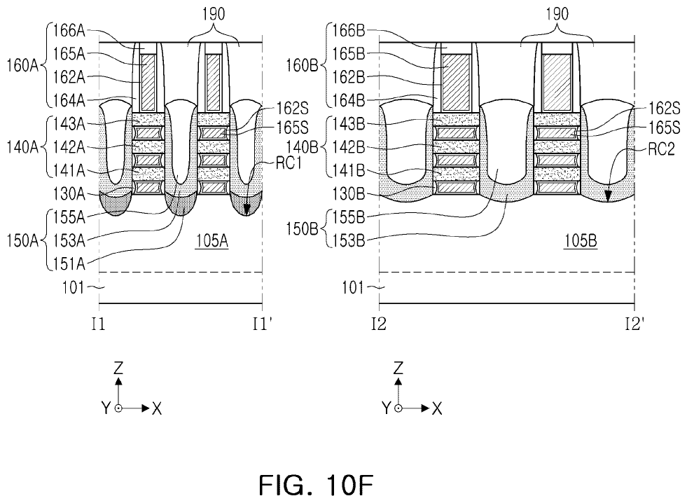

Referring to FIG. 2, a portion of the first active pattern 105A positioned on both sides of the first gate structures 160A may be recessed, and first source/drain patterns 150A may be formed in the recessed region (hereinafter referred to as “first recesses RC1”). Similarly, a portion of the second active pattern 105B positioned on both sides of the second gate structures 160B may be recessed, and second source/drain patterns 150B may be formed in the recessed region (hereinafter referred to as “second recesses RC2”). The first and second recesses RC1 and RC2 may be formed to have different depths or levels LB1 and LB2, respectively. The widths of the first and second recesses RC1 and RC2 in the first direction (e.g., X-direction) may be defined by distances between the adjacent first and second gate structures 160A and 160B, e.g., first and second distances D1 and D2. In terms of actual process, the widths of the first and second recesses RC1 and RC2 may be self-aligned by the dummy gate structures for forming the gate structures (see FIGS. 10A and 10C).

As described above, the first and second transistors 100A and 100B may have different gate structure distances D1 and D2, such that the widths of the open regions for the recesses in the first direction (e.g., X-direction) may be different, and the recess formation depth and the electrical properties (especially, lower leakage current) thereof may be changed accordingly.

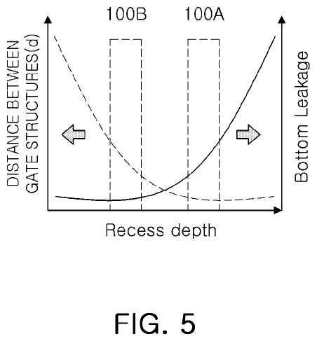

FIG. 5 is a graph indicating a change in recess depth depending on a distance between gate structures and a change in lower leakage current between elements depending on a recess depth. Here, “lower leakage current” may refer to a leakage current occurring between source/drain patterns adjacent to each other below the active pattern.

Referring to FIG. 2 together with FIG. 5, under the same etching conditions (e.g., etching time), a depth would increase as a width of the open region, e.g., the distance between the adjacent gate structure, is smaller. Even when a separate process of forming the recess is applied, unless the process conditions are significantly changed, the depth LB1 of the first recess RC1 of the first transistor 100A may be larger than the depth LB2 of the second recess RC2 of the second transistor 100B under general changing conditions.

In the first transistor 100A, as the first recess RC1 may have the relatively large depth LB1, and the first width S1 of the first gate structure 160A is also relatively small, the adjacent first source/drain patterns 150A may be disposed closer to each other than the other second source/drain patterns 150B adjacent to each other. Accordingly, the first transistor 100A may be worse than the second transistor 100B in terms of lower leakage current. To suppress the lower leakage current, as illustrated in FIGS. 2 and 3, the first source/drain patterns 150A of the first transistor 100A may include a high-resistivity bottom epitaxial layer 151A (also referred to as “first high-resistivity bottom epitaxial layer 151A” in some example implementations) below the first and second epitaxial layers 153A and 155A. The second source/drain patterns 150B of the second transistor 100B employed in the example implementation may include a third epitaxial layer 153B and a fourth epitaxial layer 155B without a high-resistivity bottom epitaxial layer.

Referring to FIG. 2, each of the first source/drain patterns 150A may include a high-resistivity bottom epitaxial layer 151A in the first recess RC1, a first epitaxial layer 153A disposed on the high-resistivity bottom epitaxial layer 151A and connected to side surfaces of the first channel patterns 140A, and a second epitaxial layer 155A on the first epitaxial layer 153A. Each of the second source/drain patterns 150B may include a third epitaxial layer 153B disposed on the side surfaces of the second channel patterns 140B, and a fourth epitaxial layer 155B on the third epitaxial layer 153B.

In the example implementation, the high-resistivity bottom epitaxial layer 151A may include a high-resistivity material layer. For example, the high-resistivity bottom epitaxial layer 151A may include at least one of undoped Si, SiB and SiN.

Also, a composition and/or a concentration of impurities of the second and fourth epitaxial layers 155A and 155B may be different from a composition and/or a concentration of impurities of the first and third epitaxial layers 153A and 153B, respectively. For example, the second and fourth epitaxial layers 155A and 155B may include a material advantageous for forming a low-resistivity contact, and the first and third epitaxial layers 153A and 153B may include a material advantageous for crystal growth, which will be described in greater detail later.

The first and second source/drain patterns 150A and 150B may be in contact with both side surfaces of the first and second channel patterns 140A and 140B in the first direction (e.g., X-direction) by the first and third epitaxial layers 153A and 153B, respectively.

The bottom levels LB1 and LB2 of the first and second source/drain patterns 150A and 150B may be determined by bottom depths of the first and second recesses RC1 and RC2, respectively. In the example implementation, a bottom level LB1 of the first source/drain patterns 150A may be lower than a bottom level LB2 of the second source/drain patterns 150B (see the description in FIG. 5).

As described above, in the example implementation, the first source/drain patterns 150A may include a high-resistivity bottom epitaxial layer 151A to prevent lower leakage current, whereas the second transistor 100B may be relatively stable in terms of lower leakage current as compared to the first transistor 100A (see the explanation in reference to FIG. 5), such that in the second source/drain patterns 150B, the third epitaxial layer 153B may be in direct contact with the internal surface of the second recess RC2 of the second active pattern 105B without the high-resistivity bottom epitaxial layer.

Accordingly, the fourth epitaxial layer 155B may extend further toward the second recess RC2, and may increase the volume of the fourth epitaxial layer 155B, which is advantageous for a low-resistivity contact in the second source/drain patterns 150B. Accordingly, as illustrated in FIG. 2, the fourth epitaxial layer 155B may have a portion overlapping the lowermost channel pattern 141B of the second channel patterns 140B in the horizontal direction (e.g., X-direction). As described above, the second transistor 100B may be effectively used up to the lowermost channel pattern 141B.

To more effectively use the lowermost channel pattern 141B, in the example implementation, a bottom level L4 of the fourth epitaxial layer 155B may be positioned lower than a lower surface level Lb of the lowermost channel pattern 141B. That is, the fourth epitaxial layer 155B may overlap almost the entirety of the lowermost channel pattern 141B in the horizontal direction (e.g., X-direction).

In this respect, the bottom level L3 of the third epitaxial layer 153B may be positioned lower than the upper surface level La of the region of the second active pattern 105B, on which the second channel patterns 140B are disposed, e.g., the second channel patterns 140B can be primarily disposed on the upper surface level La, with a portion extending below the upper surface level La.

Referring to FIG. 2, similarly to the third and fourth epitaxial layers 153B and 155B, in the first source/drain patterns 150A, the bottom level L2 of the second epitaxial layer 155A may also be lower than the lower surface level Lb of the lowermost channel pattern 141A among the first channel patterns 140A. The bottom level L1 of the first epitaxial layer 153A may be positioned lower than the upper surface level La of the region of the first active pattern 105A, at which the first channel patterns 140A are disposed.

The optional omission of the high-resistivity bottom epitaxial layer 151A in the example implementation may be implemented by forming the first and second source/drain patterns 150A and 150B in other processes (see FIGS. 10A to 10F).

As described above, the second and fourth epitaxial layers 155A and 155B may include a material advantageous for forming a low-resistivity contact, and in some example implementations, the first and third epitaxial layers 153A and 153B may include the same material, and the second and fourth epitaxial layers 155A and 155B may include the same material. The first and third epitaxial layers 153A and 153B may include a material advantageous for crystal growth. Compositions and/or concentrations of impurities of the second and fourth epitaxial layers 155A and 155B may be different from compositions and/or concentrations of impurities of the first and third epitaxial layers 153A and 153B, respectively.

In some example implementations, the second and fourth epitaxial layers 155A and 155B may have concentrations of impurities higher than concentrations of impurities of the first and third epitaxial layers 153A and 153B, respectively. In some example implementations (particularly, P-type transistors), the second and fourth epitaxial layers 155A and 155B may include higher concentrations of germanium than concentrations of germanium of the first and third epitaxial layers 153A and 153B, respectively.

For example, the first and second source/drain patterns 150A and 150B may include Si, SiGe or Ge, and may be doped with specific impurities depending on the N-type or P-type transistor. Also, the first and second source/drain patterns 150A and 150B may have different materials or different shapes.

In the case of a P-type transistor, the first and second source/drain patterns 150A and 150B may include silicon-germanium (SiGe) and may be doped with P-type impurities (e.g., boron B, indium (In), gallium (Ga)). The cross-section (Y-Z cross-section) of the first and second source/drain patterns 150A and 150B may be pentagonal (see FIG. 3).

In some example implementations, the first and third epitaxial layers 153A and 153B and the second and fourth epitaxial layers 155A and 155B may have different compositions. The first and third epitaxial layers 153A and 153B may include silicon-germanium (SiGe) doped with P-type impurities. In some example implementations, the first and third epitaxial layers 153A and 153B may include SiGe having a first concentration of germanium (Ge), and the second and fourth epitaxial layers 155A and 155B may include SiGe having a second concentration of germanium (Ge) greater than the first concentration. For example, the first concentration may be 5 at % to 20 at %, and the second concentration may be 20 at % to 60 at %. In some example implementations, the second and fourth epitaxial layers 155A and 155B may have a concentration of P-type impurities higher than that of the first and third epitaxial layers 153A and 153B.

In the case of an N-type transistor, the first and second source/drain patterns 150A and 150B may include silicon and may be doped with N-type impurities (e.g., phosphorus (P), nitrogen (N), arsenic (As), antimony (Sb), or bismuth (Bi)). The cross-section (Y-Z cross-section) of the first and second source/drain patterns 150A and 150B may be a hexagon or a polygon having gentle angles.

For example, the first and third epitaxial layers 153A and 153B may include silicon which may be intentionally undoped or doped with N-type impurities (e.g., phosphorus (P)) in a first concentration, and the second and fourth epitaxial layers 155A and 155B may include silicon doped with N-type impurities in a second concentration higher than the first concentration.

Referring to FIGS. 2 and 4, the first gate structure 160A may include a first gate electrode 165A extending in the second direction (e.g., Y-direction) and surrounding the first channel patterns 140A, and a first gate insulating layer 162A disposed between the first gate electrode 165A and the first channel patterns 140A. The first gate structure 160A may further include first gate spacers 164A disposed on side surfaces of the first gate electrode 165A, and a first gate capping layer 166A disposed on the first gate electrode 165A.

Similarly, referring to FIGS. 2 and 4, the second gate structure 160B may include a second gate electrode 165B extending in the second direction (e.g., Y-direction) and surrounding the second channel patterns 140B, and a second gate insulating layer 162B disposed between the second gate electrode 165B and the second channel patterns 140B. The second gate structure 160B may further include second gate spacers 164B disposed on side surfaces of the second gate electrode 165B, and a second gate capping layer 166B disposed on the second gate electrode 165B. A portion of components of the second gate structure 160B may have the same material and/or structure as that of a portion of components of the first gate structure 160A. For example, the second gate spacers 164B and the second gate capping layer 166B may include the same material as a material of the first gate spacers 164A and the first gate capping layer 166A, respectively.

Referring to FIGS. 2 and 4, the first gate insulating layer 162A may surround the first channel patterns 140A, respectively, and the second gate insulating layer 162B may surround the second channel patterns 140B, respectively. In some example implementations, the first and second gate insulating layers 162A and 162B may be disposed on protruding surfaces of the first and second active patterns 105A and 105B, respectively, and may have portions extending to an upper surface of the element isolation layer 110 in the second direction (e.g., Y-direction).

The first and second gate insulating layers 162A and 162B may include a plurality of dielectric films. In some example implementations, the first and second gate insulating layers 162A and 162B may include an interfacial insulating film stacked in order on surfaces of the first and second channel patterns 140A and 140B, respectively, and one or more high-k dielectric films. For example, the interfacial insulating film may include silicon oxide or silicon oxynitride. The high-k dielectric film may be a dielectric material having a dielectric constant higher than that of silicon oxide (SiO₂), for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and prascodymium oxide (Pr₂O₃).

The first and second gate insulating layers 162A and 162B may extend in the second direction (e.g., Y-direction) and may be disposed on side surfaces of the first and second gate electrodes 165A and 165B. In some example implementations, the first and second gate insulating layers 162A and 162B may extend between the first and second gate electrodes 165A and 165B and the first and second gate spacers 164A and 164B.

The first and second gate electrodes 165A and 165B may be formed fill a space between the first and second channel patterns 140A and 140B and may be formed on an upper portion of the uppermost channel layer on upper portions of the first and second active patterns 105A and 105B, respectively. The first and second gate insulating layers 162A and 162B may be disposed between the first and second gate electrodes 165A and 165B and the first and second channel patterns 140A and 140B, respectively. The first and second gate electrodes 165A and 165B may include a conductive material. For example, the first and second gate electrodes 165A and 165B may include a metal nitride such as titanium nitride (TiN), tantalum nitride (TaN), or tungsten nitride (WN), and/or a metal material such as aluminum (Al), tungsten (W), or molybdenum (Mo), or a semiconductor material such as doped polysilicon. In some example implementations, at least one of the first and second gate electrodes 165A and 165B may include two or more multilayers. In some example implementations, the first and second gate electrodes 165A and 165B may include different conductive materials.

The first and second gate spacers 164A and 164B may be disposed on both side surfaces of the first and second gate electrodes 165A and 165B, respectively. The first and second gate spacers 164A and 164B may insulate the first and second source/drain patterns 150A and 150B and the first and second gate electrodes 165A and 165B from each other. In some example implementations, the gate spacers 164 may be formed in a multilayer structure. For example, the first and second gate spacers 164A and 164B may include oxide, nitride and oxynitride, and may be formed of a low-K film in particular. The first and second gate capping layers 166A and 166B may be disposed on the first and second gate electrodes 165A and 165B between the first and second gate spacers 164A and 164B, respectively.

Referring to FIG. 2, the first and second internal spacers 130A and 130B may be disposed on both side surfaces in the first direction (e.g., X-direction) of the gate electrode portions positioned between the first and second channel patterns 140A and 140B, respectively. The first and second gate electrodes 165A and 165B may be spaced apart from the first and second source/drain patterns 150A and 150B by the first and second internal spacers 130A and 130B, respectively, and may be electrically isolated. The side surfaces of the first and second internal spacers 130A and 130B in contact with the first and second gate electrodes 165A and 165B may have convex curves, but an example implementation thereof is not limited thereto. The first and second internal spacers 130A and 130B may include a low-K material. For example, the first and second internal spacers 130A and 130B may include oxide, nitride, and oxynitride.

As described above, the semiconductor device 100 according to the example implementation may include a first transistor 100A including a first channel pattern 140A, a first source/drain patterns 150A, and a first gate structure 160A, and a second transistor 100B including a second channel pattern 140B, a second source/drain patterns 150B, and a second gate structure 160B, each of which may be implemented as a gate-all-around type field effect transistor.

The first and second contact structures 180A and 180B may penetrate the interlayer insulating layer 190, may be connected to the first and second source/drain patterns 150A and 150B, respectively, and may apply electrical signals to the first and second source/drain patterns 150A and 150B. The first and second contact structures 180A and 180B may be disposed on the first and second source/drain patterns 150A and 150B, respectively, as illustrated in FIGS. 1 to 3. In some example implementations, the first and second contact structures 180A and 180B may be disposed to have a relatively longer length in the second direction (e.g., Y-direction) than those of the first and second source/drain patterns 150A and 150B, respectively. Each of the first and second contact structures 180A and 180B may have an inclined side surface of which a lower width may decrease further than an upper width depending on an aspect ratio, but an example implementation thereof is not limited thereto. The first and second contact structures 180A and 180B may extend downwardly, for example, to a region below the uppermost channel pattern. In the example implementation, since a high-resistivity bottom epitaxial layer may not be provided in the second source/drain patterns 150B of the second transistor 100B, the third epitaxial layer 153B and the fourth epitaxial layer 155B may be formed to have a sufficient volume. In particular, by independently performing the growth process for the second source/drain patterns 150B, the fourth epitaxial layer 155B, which is advantageous for a low-resistivity contact, may be formed to have a sufficient volume, and the second contact structure 180B may be stably connected to the fourth epitaxial layer 155B.

For example, each of the first and second contact structures 180A and 180B may include metal nitride, such as titanium nitride (TiN), tantalum nitride (TaN), or tungsten nitride (WN), and/or a metal material, such as aluminum (Al), tungsten (W), or molybdenum (Mo).

The interlayer insulating layer 190 may be disposed to cover the first and second source/drain patterns 150A and 150B, the first and second gate structures 160A and 160B, and the element isolation layer 110. For example, the interlayer insulating layer 190 may include at least one of an oxide, a nitride, and an oxynitride, and may include a low-K material.

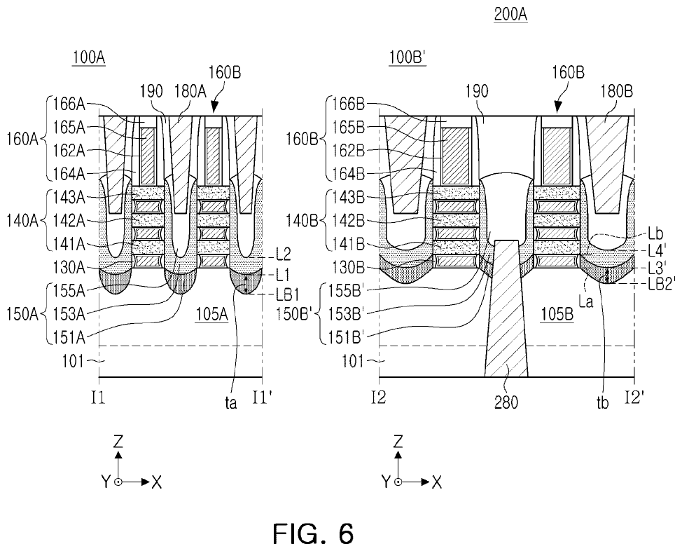

FIG. 6 is cross-sectional diagrams illustrating a semiconductor device according to an example implementation.

Referring to FIG. 6, a semiconductor device 200A according to the example implementation may be similar to the semiconductor device 200 illustrated in FIGS. 1 to 4, other than the configuration in which the second source/drain pattern 150B′ may further include a second high-resistivity bottom epitaxial layer 151B′, the configuration in which bottom levels L3′ and L4′ of the third and fourth epitaxial layers 153B′ and 155B′ are partially changed, and the configuration in which a portion of the second source/drain pattern 150B′ are connected to the lower contact structure 280. Also, the components in the example implementation may be understood by referring to the descriptions of identical or similar components of the semiconductor device 200 illustrated in FIGS. 1 to 4, unless otherwise indicated.

The second source/drain patterns 150B′ employed in the example implementation may further include a second high-resistivity bottom epitaxial layer 151B between the second active pattern 105B and the third epitaxial layer 153B. The second high-resistivity bottom epitaxial layer 151B may be grown from a surface of the second recess RC2 of the second active pattern 105B. Similarly to the high-resistivity bottom epitaxial layer of the first source/drain patterns 150A, e.g., the first high-resistivity bottom epitaxial layer 151A, the second high-resistivity bottom epitaxial layer 151B′ may include a high-resistivity material layer. For example, the second high-resistivity bottom epitaxial layer 151B′ may include at least one of undoped Si, SiB and SiN.

A bottom level LB1 of the first high-resistivity bottom epitaxial layer 151A of the first transistor 100A may be lower than a bottom level LB2′ of the second high-resistivity bottom epitaxial layer 151B′ of the second transistor 100B′. In the example implementation, the second high-resistivity bottom epitaxial layer 151B′ may have a thickness tb smaller than a thickness ta of the first high-resistivity bottom epitaxial layer 151A. For example, the thickness tb of the second high-resistivity bottom epitaxial layer 151B′ may be 10 nm or lower (e.g., 7 nm or lower). As described above, even when the second high-resistivity bottom epitaxial layer 151B′ is included, since the second high-resistivity bottom epitaxial layer 151B′ has a reduced thickness, the fourth epitaxial layer 155B′ may further extend toward the second recess RC2, and similarly to the aforementioned example implementation, the second source/drain patterns 150B′ may have the fourth epitaxial layer 155B′ which is advantageous for a low-resistivity contact with sufficient volume.

As illustrated in FIG. 6, the fourth epitaxial layer 155B′ may partially overlap the lowermost channel pattern 141B among the second channel patterns 140B in the horizontal direction (e.g., X-direction), rather than entirely. Accordingly, the lowermost channel pattern 141B may be effectively used in the second transistor 100B. Also, the bottom level L3′ of the third epitaxial layer 153B′ may be positioned at or lower than the upper surface level La of the region of the second active pattern 105B, at which the second channel patterns 140B are disposed.

The semiconductor device 200A according to the example implementation may further include a lower contact structure 280 penetrating the substrate 101 and connected to the second source/drain pattern 150B′ of the second transistor 100B′. As described above, since the second high-resistivity bottom epitaxial layer 151B′ is employed with a relatively thin thickness tb, and the fourth epitaxial layer 155B′ extends further toward the second recess RC2, the lower contact structure 280 may be stably connected to the fourth epitaxial layer 155B′ for a low-resistivity contact.

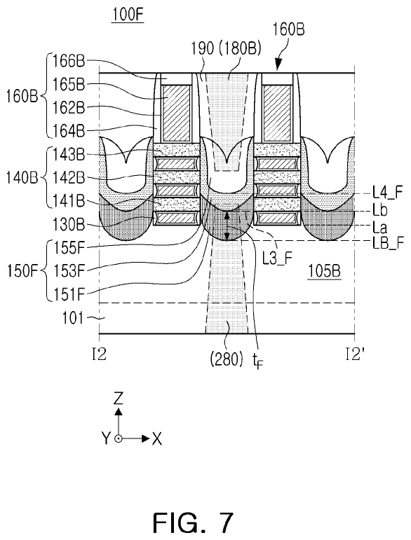

The semiconductor devices 200 and 200A (in particular, the second transistor 100B and 100B′) according to the example implementations have a structure advantageous for forming a stable low-resistivity contact structure, which will be described in detail with reference to FIG. 7.

FIG. 7 is a cross-sectional diagram describing a connection state (indicated by a dotted line) of the contact structures 180B and 280 in the second source/drain patterns 150F according to a comparative example. The second source/drain patterns 150F illustrated in FIG. 7 may be understood as a structure grown simultaneously with the first source/drain patterns (e.g., 150A in FIG. 2), differently from the aforementioned example implementations.

Referring to FIG. 7, a second high-resistivity bottom epitaxial layer 151F may have a relatively large thickness tp. As described above, in the comparative example, when the second high-resistivity bottom epitaxial layer 151F is grown simultaneously with the first high-resistivity bottom epitaxial layer (151A in FIG. 2) of another type of element (e.g., 100A in FIG. 2), since a specific process for selective bottom growth (e.g., repeating the growth and etching processes) is used, the second high-resistivity bottom epitaxial layer 151F may be grown to have a thickness t_{F} greater than the thickness ta of the first high-resistivity bottom epitaxial layer 151A. Accordingly, the second high-resistivity bottom epitaxial layer 151F may be grown to cover (at least a portion of) the lowermost second channel pattern 141B. Accordingly, the third epitaxial layer 153F and also the bottom level L4_F of the fourth epitaxial layer 155F may be positioned at a level higher than a level of the upper surface of the lowermost second channel pattern 141B.

Accordingly, when the lower contact structure 280 is formed with the same structure as the lower contact structure 280 illustrated in FIG. 6, due to the second high-low bottom epitaxial layer 151F having a greater thickness, connection to the fourth epitaxial layer 155F may not be performed. For example, an upper end of the lower contact structure 280 may be positioned in the third epitaxial layer 153F. In this case, the lower contact structure 280 may have high contact resistance.

In the comparative example, since the fourth epitaxial layer 155F may be formed simultaneously with the second epitaxial layer (155A in FIG. 2) formed in a relatively narrow space, as illustrated in FIG. 7, the fourth epitaxial layer 155F may not sufficiently fill the space and may have a concave upper surface. In this case, the upper contact structure 180B may extend excessively downwardly, such that it may be difficult to assure a process margin.

As described above, considering the poor connection of the contact structure in the comparative example illustrated in FIG. 7, by forming the second source/drain patterns 150B and 150B′ according to the example implementation without a high-resistivity bottom epitaxial layer or to have a reduced thickness, and forming the fourth epitaxial layer for the low-resistivity contact to have a sufficient volume, the upper contact structure 180B and also the lower contact structure 280 may be easily formed to have a stable low-resistivity contact.

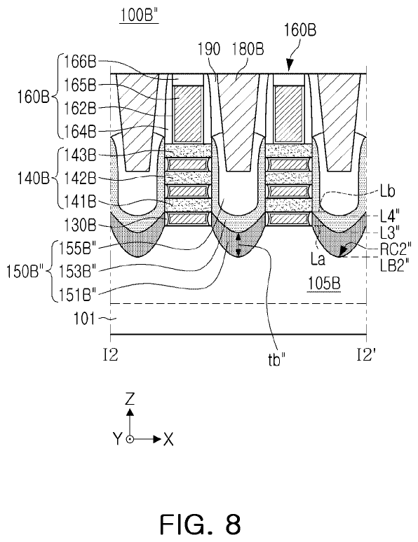

FIG. 8 is a cross-sectional diagram illustrating a semiconductor device (second transistor) according to an example implementation. The second transistor 100B″ may be understood as a portion B of the semiconductor device 200 and 200A implemented together with the first transistor 100A in FIG. 2 and FIG. 6.

Referring to FIG. 8, the second transistor 100B″ according to the example implementation may be understood as being similar to the semiconductor device 200 and the second transistor 100B illustrated in FIGS. 1 to 4, other than the configuration in which the second recesses RC2″ are formed with a relatively large depth LB2″, the configuration further including a second high-resistivity bottom epitaxial layer 151B″ with a relatively large thickness tb “, and the configuration in which the bottom levels L3” and L4″ of the third and fourth epitaxial layers 153B″ and 155B″ are partially changed. Also, the components in the example implementation may be understood by referring to the descriptions of the same or similar components of the second transistor 100B illustrated in FIGS. 1 to 4, unless otherwise indicated.

The second transistor 100B according to the example implementation may use the lowermost channel pattern 141B by sufficiently lowering the fourth epitaxial layer 153B″ by forming the second recess RC2″ to have a deeper depth. In the example implementation, the bottom level LB2″ of the second high-resistivity bottom epitaxial layer 151B″ may be formed at a level lower than a level of the upper surface level La of one region of the second active pattern 105B in which the second channel patterns 140B are disposed. That is, by forming the second recess RC2 having a depth almost corresponding to the thickness of the second high-resistivity bottom epitaxial layer 151B″, the second high-resistivity bottom epitaxial layer 151B″ having a relatively large thickness tb″ may be allowed. For example, the bottom level LB2″ of the second high-resistivity bottom epitaxial layer 151B″ may be formed lower by 5 nm to 15 nm than the upper surface level La of the second active pattern 105B.

As described above, by forming the second recess RC2 to have a depth almost corresponding to the thickness of the second high-resistivity bottom epitaxial layer 151B″, even when the second high-resistivity bottom epitaxial layer 151B″ having a sufficient thickness tb″ is included, the fourth epitaxial layer 155B″ may further extend toward the second recess RC2″, and similarly to the aforementioned example implementation, the second source/drain patterns 150B″ may have the fourth epitaxial layer 155B″ which may be advantageous for a low-resistivity contact with a sufficient volume.

As illustrated in FIG. 8, the fourth epitaxial layer 155B″ may overlap the lowermost channel pattern 141B among the second channel patterns 140B in the horizontal direction (e.g., X-direction). Also, the bottom level L3″ of the third epitaxial layer 153B″ may be positioned at a level lower than a level of the upper surface level La of the region of the second active pattern 105B in which the second channel patterns 140B are disposed.

In the second transistor 100B″ according to the example implementation, by forming the second recess RC2″ to have a deep depth, the fourth epitaxial layer 155B″ for the low-resistivity contact may be formed to have a sufficient volume, and accordingly, the upper contact structure and also the lower contact structure may be easily formed to have a stable low-resistivity contact.

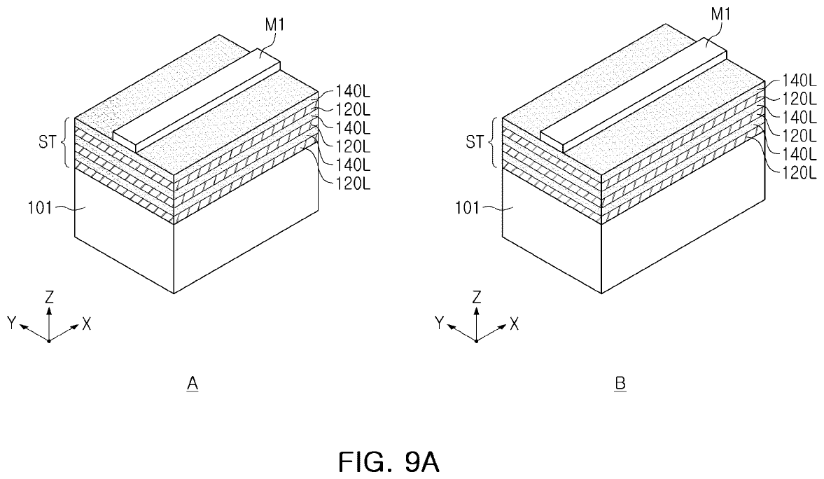

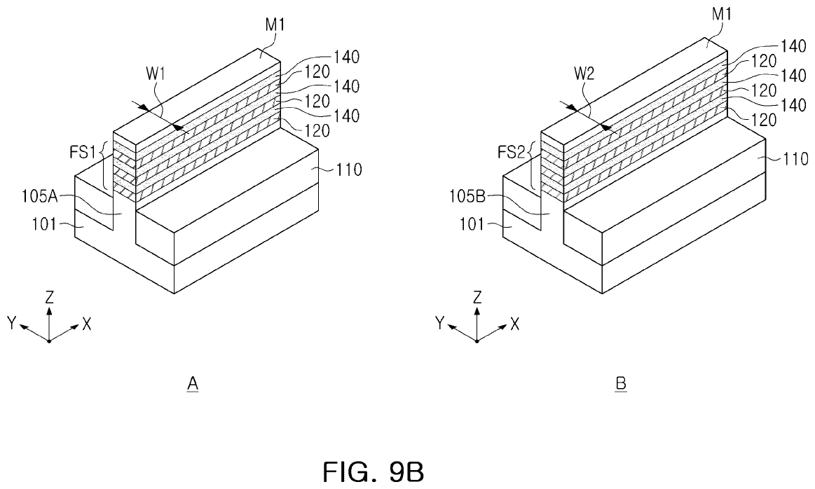

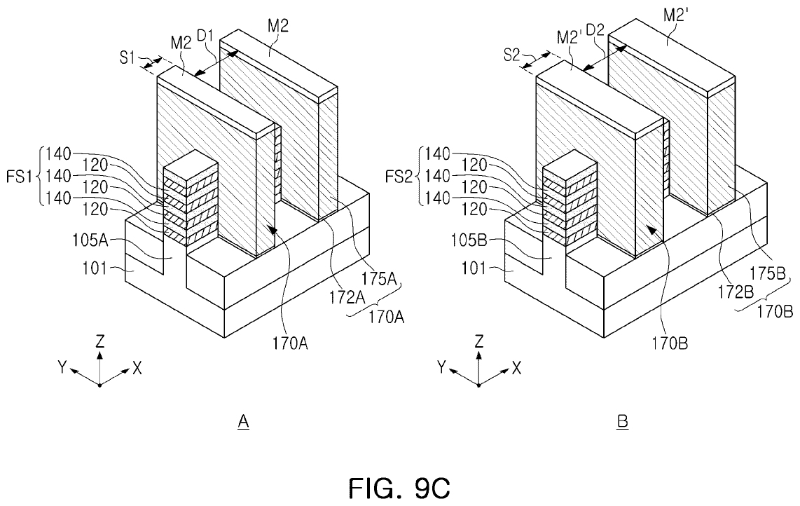

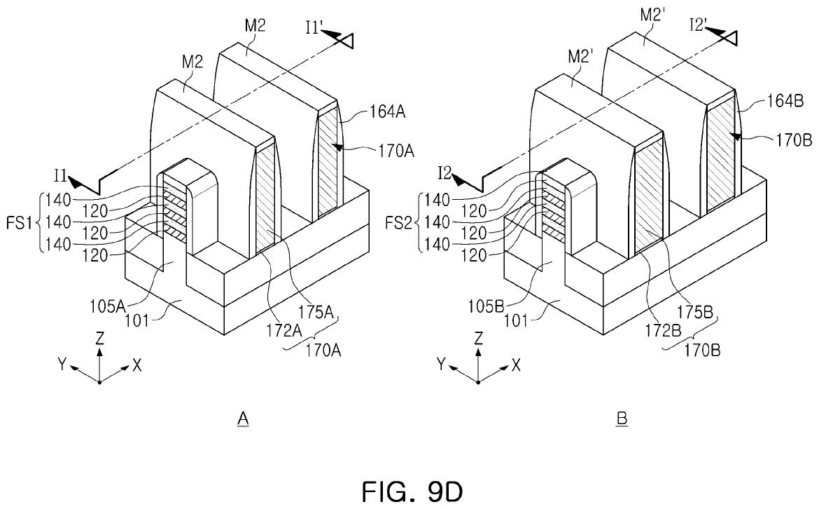

FIGS. 9A to 9D are cross-sectional diagrams illustrating a portion of processes (forming fin-type structures FS1 and FS2 and dummy gate structures 170A and 170B of a method of manufacturing a semiconductor device according to an example implementation, and may be understood as a manufacturing method of the semiconductor device 200 illustrated in FIGS. 1 to 4. The forming the fin-type structures FS1 and FS2 and the dummy gate structures 170A and 170B may be performed in common in a first region A and a second region B of the substrate 101.

First, referring to FIG. 9A, a semiconductor stack ST may be formed by alternately stacking first semiconductor layers 120L and second semiconductor layers 140L on an upper surface of the substrate 101. The semiconductor stack ST may be formed across the first region A and the second region B of the substrate 101. Each of the first and second regions A and B may form a first mask pattern M1 extending in the first direction (e.g., X-direction).

The first semiconductor layers 120L may be removed in a subsequent process and may be used as a sacrificial layer, and the second semiconductor layers 140L may be used as a channel layer. The first semiconductor layers 120L and the second semiconductor layers 140L may include a semiconductor material such as silicon (Si) or silicon germanium (SiGe), and may include different semiconductor materials. The first semiconductor layers 120L may be formed of a material having a high etch selectivity with respect to the second semiconductor layers 140L. The second semiconductor layers 140L may include impurities, but an example implementation thereof is not limited thereto.

In some example implementations, the first semiconductor layers 120L may include silicon germanium (SiGe), and the second semiconductor layers 140L may include silicon (Si). The first semiconductor layers 120L and the second semiconductor layers 140L may be grown on the substrate 101 by an epitaxial growth process. Each of the first semiconductor layers 120L and the second semiconductor layers 140L may have a thickness ranging from about 1 nm to 100 nm.

A width of the first mask pattern M1 in the second direction (e.g., Y-direction) may be provided as the same width in the first and second regions A and B. For example, a width of the first mask pattern M1 may determine widths of the first and second active patterns and widths of the first and second channel patterns.

Thereafter, referring to FIG. 9B, by removing a portion of the semiconductor stack ST and the substrate 101 using the first mask pattern M1 extending in the first direction (e.g., X-direction), the first and second fin-type structures FS1 and FS2 may be formed in the first and second regions A and B of the substrate 101, respectively.

In the process, first and second active patterns 105A and 105B obtained by partially removing the substrate 101 may be formed together with first and second fin-type structures FS1 and FS2. The first and second active pattern 105A and 105B may include a structure protruding from an upper surface of the substrate 101 by removing a portion of the substrate 101, and the first and second fin-type structures FS1 and FS2 may include first semiconductor patterns 120 and second semiconductor patterns 140 alternately stacked on the first and second active patterns 105A and 105B, respectively. The first and second active patterns 105A and 105B and the first and second fin-type structures FS1 and FS2 may be formed in a line shape extending in one direction, for example, in the first direction (e.g., X-direction). In the region from which a portion of the substrate 101 is removed, the element isolation layer 110 may be formed by filling an insulating material and etching back a portion of the first and second active patterns 105A and 105B to protrude. That is, the upper surface of the element isolation layer 110 may be etched back to a level lower than a level of upper surfaces of the first and second active patterns 105A and 105B.

Thereafter, referring to FIG. 9C, the first and second dummy gate structures 170A and 170B extending in the second direction (e.g., Y-direction) to intersect a portion region of the first and second fin-type structures FS1 and FS2 may be formed.

The first and second dummy gate structures 170A and 170B may be sacrificial structures for forming the first and second gate structures 160A and 160B illustrated in FIG. 2 through a subsequent process. The first and second dummy gate structures 170A and 170B may have a line shape extending in the second direction (e.g., Y-direction) to intersect a portion region of the first and second fin-type structures FS1 and FS2, and may be arranged and spaced apart from each other in the first direction (e.g., X-direction).

First and second sacrificial gate layers 172A, 172B, 175A, and 175B stacked in order throughout the first and second regions A and B of the substrate 101 (particularly, an element isolation layer 110) may be formed, and the stack may be patterned using a second mask pattern M2 and M2′, thereby forming first and second dummy gate structures 170A and 170B extending in the second direction (e.g., Y-direction). The first and second dummy gate structures 170A and 170B may be formed in different arrangements by designing the second mask pattern M2 and M2′ differently. Specifically, similarly to the first and second gate structures 160A and 160B described in FIGS. 1 and 2, each of the first dummy gate structures 170A may have a first width S1 and may be arranged to be spaced apart from each other by a first distance D1 in the first direction (e.g., X-direction). The second dummy gate structures 170B may have a second width S2 greater than the first width S1 and may be arranged to be spaced apart from each other by a second distance D2 greater than the first distance D1 in the first direction (e.g., X-direction). In some example implementations, the first sacrificial gate layers 172A, 172B may include silicon oxide and the second sacrificial gate layers 175A and 175B may include polysilicon. The second mask patterns M2 and M2′ may include silicon oxide and/or silicon nitride.

Thereafter, referring to FIG. 9D, gate spacers 164A and 164B may be formed on both side surfaces of each of the first and second dummy gate structures 170A and 170B and on both side surfaces of each of the first and second fin-type structures FS1 and FS2, respectively.

A spacer material layer may be conformally formed on the first and second dummy gate structures 170A and 170B and the first and second fin-type structures FS1 and FS2, and anisotropic etching may be applied, such that gate spacers 164A and 164B may be formed on both side surfaces of the first and second dummy gate structures 170A and 170B, respectively. A portion of the gate spacers 164A and 164B may be provided on both side surfaces of each of the first and second fin-type structures FS1 and FS2 and on both side surfaces of the exposed first and second active patterns 105A and 105B. The both side surfaces on which the gate spacers 164A and 164B are formed may be opposite side surfaces positioned in the first direction (e.g., X-direction) of the first and second dummy gate structures 170A and 170B. The gate spacers 164A and 164B may include, for example, at least one of SiO, SiN, SiCN, SiOC, SiON, and SiOCN.

FIGS. 10A to 10F are perspective diagrams illustrating the other portion of processes of a method of manufacturing a semiconductor device according to an example implementation. FIGS. 10A to 10F illustrate cross-sections of the structures in FIG. 9D taken along lines I1-I1′ and I2-I2′, respectively, and may be understood as cross-sections corresponding to the cross-sections illustrated in FIG. 2.

Referring to FIG. 10A, a first photo mask PR1 may be formed in the second region B, and a portion region of the first fin-type structure FS1 positioned on both sides of the first dummy gate structures 170A in the first region A may be removed, thereby forming a first recess RC1.

In the process, the first channel patterns 140A may be formed from the second semiconductor layers 140. The first semiconductor layers 120 patterned together with the first channel patterns 140A may remain as a first sacrificial pattern. The first recess RC1 may be formed on both sides of the first dummy gate structures 170A by removing the exposed portions of the first fin-type structure FS1 using the second mask pattern M2 and the first gate spacers 164A as a mask. The first recess RC1 may be formed to be etched up to a portion of the first active pattern 105A. A bottom level LB1 of the first recess RC1 may be provided to have a relatively deep depth. Through this process of forming the recess, a length of the first channel patterns 140A in the first direction (e.g., X-direction) may be determined.

In the example implementation, by selectively etching a portion of the first semiconductor layers 120 through the exposed side surfaces of the first semiconductor layers 120 and filling the removed region with an insulating material, the desired first internal spacers 130A may be formed

Thereafter, referring to FIG. 10B, the first source/drain patterns 150A may be formed in the first recess RC1 positioned on both sides of the first dummy gate structures 170A in the first region A.

In the process, a high-resistivity bottom epitaxial layer 151A may be formed in the first recess RC1, and a first epitaxial layer 153A and a second epitaxial layer 155A may be formed in order on the first high-resistivity bottom epitaxial layer 151A. The first epitaxial layer 153A may be grown on the first high-resistivity bottom epitaxial layer 151A to be connected to side surfaces of the first channel patterns 140A, and the second epitaxial layer 155A may be formed to be filled in an internal space of the first epitaxial layer 153A. The bottom level L2 of the second epitaxial layer 155A may also be lower than the lower surface level Lb of the lowermost channel pattern 141A among the first channel patterns 140A. The bottom level L1 of the first epitaxial layer 153A may be positioned at a level lower than a level of the upper surface level La of a region of the first active pattern 105A in which the first channel patterns 140A are disposed.

In the example implementation, the high-resistivity bottom epitaxial layer 151A may include a high-resistivity material layer. For example, the high-resistivity bottom epitaxial layer 151A may include at least one of undoped Si, SiB and SiN. The composition and/or the concentration of impurities of the second epitaxial layers 155A may be different from the composition and/or the concentration of impurities of the first epitaxial layers 153A, respectively, and the second epitaxial layers 155A may be provided with a material advantageous for forming a low-resistivity contact.

Thereafter, referring to FIG. 10C, a second photo mask PR2 may be formed in the first region A, and a portion region of the second fin-type structure FS2 positioned on both sides of the second dummy gate structures 170B in the second region B may be removed, thereby forming a second recess RC2.

The process may be performed after the first photo mask PR1 is removed. In the process, second channel patterns 140B may be formed from the second semiconductor layers 140. The first semiconductor layers 120 patterned together with the second channel patterns 140B may remain as a second sacrificial pattern. By removing the exposed portions of the second fin-type structure FS2 using the second mask pattern M2′ and the second gate spacers 164B as a mask, the second recess RC2 may be formed on both sides of the second dummy gate structures 170B. The second recess RC2 may be formed to be etched up to a portion of the second active pattern 105B. The bottom level LB2 of the second recess RC2 may be formed at a level higher than a level of the bottom level LB1 of the first recess RC1. Through the process of forming the recess, the second channel patterns 140B may have a length determined in the first direction (e.g., the X-direction).

In the example implementation, by selectively etching a portion of the first semiconductor layers 120 through the exposed side surfaces of the first semiconductor layers 120 and filling the removed region with an insulating material, the desired second internal spacers 130B may be formed.

Thereafter, referring to FIG. 10D, in the second region B, the second source/drain patterns 150B may be formed in the second recess RC2 positioned on both sides of the second dummy gate structures 170B.

In the process, the third epitaxial layer 153B and the fourth epitaxial layer 155B may be formed in order in the second recess RC2 without forming a high-resistivity bottom epitaxial layer. The third epitaxial layer 153B may be grown on an internal surface of the second recess RC2 to be connected to side surfaces of the second channel patterns 140B, and the fourth epitaxial layer 155B may be formed to be filled in an internal space of the third epitaxial layer 153B.

In the process, the third epitaxial layer 153B may be formed such that the bottom level L3 may be positioned at a level lower than a level of the upper surface level La of a region of the second active pattern 105B in which the second channel patterns 140B are disposed. Thereafter, the fourth epitaxial layer 155B may be formed to extend further toward the second recess RC2 and may have a relatively large volume. Accordingly, the fourth epitaxial layer 155B may overlap the lowermost channel pattern 141B among the second channel patterns 140B in the horizontal direction (e.g., X-direction). In the example implementation, the fourth epitaxial layer 155B may be formed such that the bottom level LA thereof may be positioned at a level lower than a level of the lower surface level Lb of the lowermost channel pattern 141B. A composition and/or a concentration of impurities of the fourth epitaxial layers 155B may be different from those of the third epitaxial layers 153B, respectively, and the fourth epitaxial layers 155B may be provided as a material advantageous for forming a low-resistivity contact.

Thereafter, referring to FIG. 10E, after the second photo mask PR2 is removed, the interlayer insulating layer 190 may be formed, and the sacrificial patterns 120 and the first and second dummy gate structures 170A and 170B may be removed, thereby forming gap regions G1 and gate space G2.

First, by forming an insulating film covering the first and second dummy gate structures 170A and 170B and the first and second source/drain patterns 150A and 150B and performing a planarization process, the interlayer insulating layer 190 may be formed. The sacrificial patterns 120 and the first and second dummy gate structures 170A and 170B may be selectively removed. First, the first and second dummy gate structures 170A and 170B may be removed together with the second mask patterns M2 and M2′, thereby forming the gate spaces G2, and the sacrificial patterns 120 exposed through the gate spaces G2 may be removed to form the gap regions G1. For example, when the sacrificial patterns 120 include silicon germanium (SiGe) and the first and second channel patterns 140A and 140B include silicon (Si), the sacrificial patterns 120 may be selectively removed by performing a wet etching process using peracetic acid as an etchant. In the removing process, the first and second source/drain patterns 150A and 150B may be protected by the interlayer insulating layer 190.

Thereafter, referring to FIG. 10F, the first and second gate structures 160A and 160B may be formed in the gap regions G1 and the gate space G2.

The first and second gate insulating layers 162A and 162B may be formed to conformally cover internal surfaces of the gap regions G1 and the gate space G2. The first and second gate electrodes 165A and 165B may be formed to fill the gap regions G1 and the gate space G2, and may be removed from an upper portion in the gate space G2 to a predetermined depth. The first and second gate capping layers 166A and 166B may be formed in the region of the gate space G2 from which the first and second gate electrodes 165A and 165B are removed. Through these processes, first and second gate structures 160A and 160B may be formed in the gap regions G1 and the gate space G2.

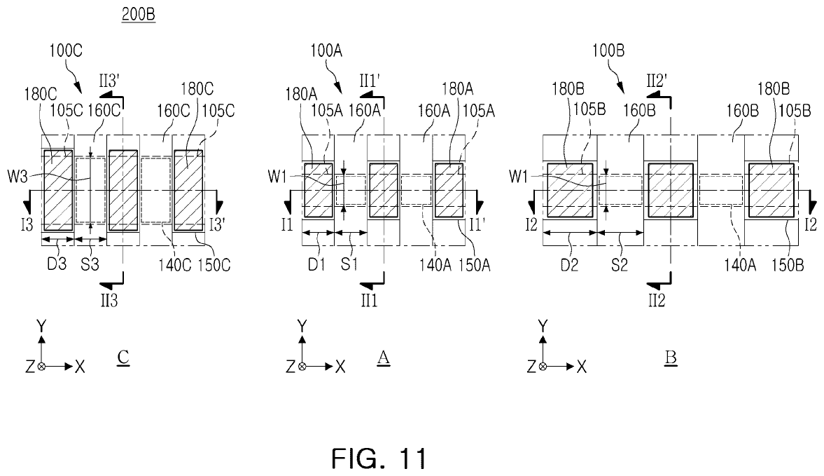

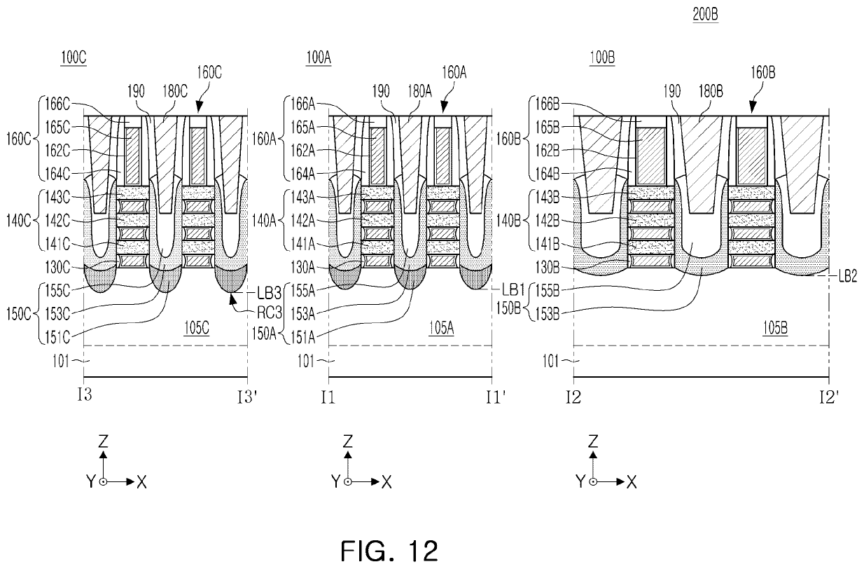

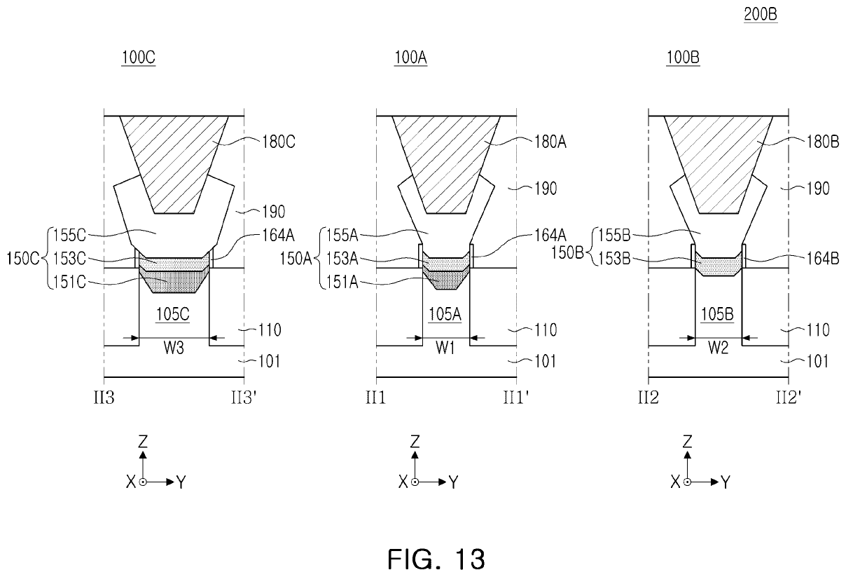

FIG. 11 is a plan diagram illustrating a semiconductor device according to an example implementation. FIG. 12 is cross-sectional diagrams illustrating a semiconductor device taken along lines I1-I1′, I2-I2′, and I3-I3′ in FIG. 11. FIG. 13 is cross-sectional diagrams illustrating a semiconductor device taken along lines II1-II1′, II2-II2′, and II3-II3′ in FIG. 1.

Referring to FIGS. 11 to 13, a semiconductor device 200B according to the example implementation may be similarly to the semiconductor device 200 illustrated in FIGS. 1 to 4, other than the configuration of further including a third transistor 100C in the other region of the substrate 101. Also, the components in the example implementation may be understood by referring to the description of the same or similar components of the semiconductor device 200 illustrated in FIGS. 1 to 4, unless otherwise indicated.

The semiconductor device 200B according to the example implementation may further include a third transistor 100C in a third region C of the substrate 101, in addition to the first and second transistors 100A and 100B.

The third transistor 100C employed in the example implementation may include third channel patterns 140C stacked and spaced apart from each other on one region of third active pattern 105C, a third gate structure 160C on the third channel patterns 140C, and a pair of third source/drain patterns 150C disposed on both sides of the third gate structure 160C, respectively. The first and second active patterns 105A and 105B of the first and second transistors 100A and 100B may have the same width W1=W2, and the third active pattern 105C of the third transistor 100C may have a width W3 different from the widths W1 and W2 of the first and second active patterns 105A and 105B. In the example implementation, the width W3 of the third active pattern 105C may be larger than the widths W1 and W2 of the first and second active patterns 105A and 105B.

Also, in the example implementation, a channel length of the third transistor 100C may be the same as a channel length of the first transistor 100A. Specifically, a length of the third channel patterns 140C in the first direction (e.g., X-direction) may be the same as a length of the first channel patterns 140A in the first direction (e.g., X-direction) and may be smaller than a length of the second channel patterns 140B in the first direction (e.g., X-direction).

Each of the third source/drain patterns 150C of the third transistor 100C may include a third high-resistivity bottom epitaxial layer 151C disposed on the third recess RC3 of the third active pattern 105C, a fifth epitaxial layer 153C disposed on the third high-resistivity bottom epitaxial layer 151C and connected to side surfaces of the third channel patterns 140C, and a sixth epitaxial layer 155C on the fifth epitaxial layer 153C.

The bottom level LB3 of the third source/drain patterns 150C may be different from the bottom level LB1 of the first source/drain patterns 150A. In the example implementation, the bottom level LB3 of the third source/drain patterns 150C may be lower than the bottom level LB1 of the first source/drain patterns 150A. In this case, the third high-resistivity bottom epitaxial layer 151C may have a thickness slightly larger than that of the first high-resistivity bottom epitaxial layer 151A.

In the example implementation, in the second source/drain patterns 150B of the second transistor 100B, the third epitaxial layer 153B may be in direct contact with the internal surface of the second recess RC2 of the second active pattern 105B without the high-resistivity bottom epitaxial layer. Accordingly, the volume of the fourth epitaxial layer 155B, which may be advantageous for the low-resistivity contact in the second source/drain patterns 150B, may be increased, and the fourth epitaxial layer 155B may overlap the lowermost channel pattern 141B among the second channel patterns 140B in the horizontal direction (e.g., X-direction). As described above, the second transistor may be effectively used from the second transistor 100B to the lowermost channel pattern 141B.

In the example implementation, the first to third source/drain patterns 150A, 150B, and 150C may be formed by different processes of forming the recesses and different epitaxial growth processes. In some example implementations, the first to third source/drain patterns 150A, 150B, and 150C may apply different process of forming the recesses, the first and third source/drain patterns 150A and 150C may be simultaneously formed by the same epitaxial growth process, and only the second source/drain patterns 150B may be formed by a different epitaxial growth process.

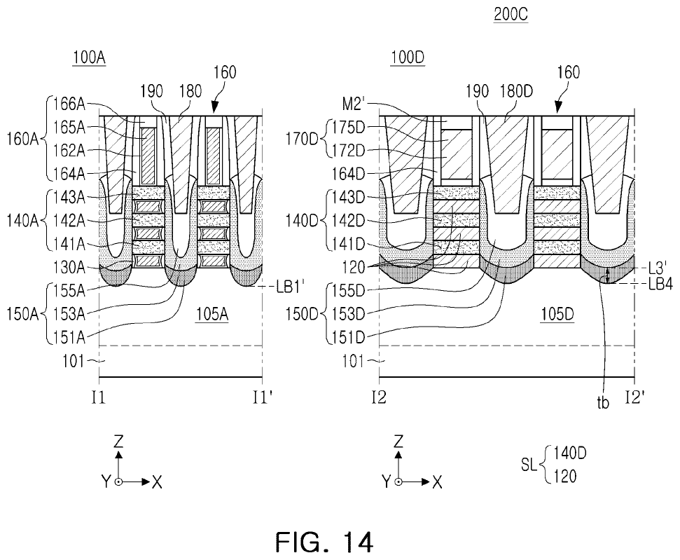

FIG. 14 is cross-sectional diagrams illustrating a semiconductor device according to an example implementation.

Referring to FIG. 14, a semiconductor device 200C according to the example implementation may be similarly to the semiconductor device 200 illustrated in FIGS. 1 to 4, other than the configuration of including a different type of peripheral circuit element 100D in the second region of the substrate 101. Furthermore, the components in the example implementation may be understood by referring to the description of the same or similar components of the semiconductor device 200 illustrated in FIGS. 1 to 4, unless otherwise indicated.

The semiconductor device 200C according to the example implementation may include, together with the first transistor 100A, a peripheral circuit element 100D as a different type of element.

Similarly to the first transistor described in FIG. 2, the first transistor 100A employed in the example implementation may include first channel patterns 140A on one region of the first active pattern 105A, first gate structures 160A extending in the second direction (e.g., Y-direction) and surrounding the first channel patterns 140A, respectively, and a pair of first source/drain patterns 150A disposed on both sides of the first gate structure 160A, respectively.

The peripheral circuit element 100D employed in the example implementation may be formed on the second active pattern 105D having the same width as a width of the first active pattern. The peripheral circuit element 100D may include a semiconductor stack SL having first semiconductor patterns 120 and second semiconductor patterns 140D alternately stacked on one region of the second active pattern 105D. Also, the peripheral circuit element 100D may include a second gate structure 170D extending in the second direction (e.g., Y-direction) and intersecting the semiconductor stack SL, and a pair of epitaxial patterns 150D disposed on both sides of the second gate structure 170D, respectively. The arrangement of the first gate structure 160A and the second gate structure 170D included in the example implementation may correspond to the arrangements of the first and second gate structures 160A and 160B described in FIGS. 1 and 2, respectively.

In the example implementation, the second gate structure 170D may be configured as a dummy gate structure and may include a second mask pattern M2′ and first and second sacrificial gate layers 172D and 175D. The first sacrificial gate layer 172D may include silicon oxide, and the second sacrificial gate layer 175D may include polysilicon. The second mask pattern M2′ may include silicon oxide and/or silicon nitride.

As illustrated in FIG. 14, the epitaxial patterns 150D of the peripheral circuit element 100D may have a bottom level LB4 higher than a bottom level LB1′ of the first source/drain patterns 150A. The epitaxial patterns 150D employed in the example implementation may further include a second high-resistivity bottom epitaxial layer 151D between the second active pattern 105D and the third epitaxial layer 153D, similarly to the second source/drain patterns 150B′ in FIG. 6. The second high-resistivity bottom epitaxial layer 151D may be grown from a surface of the second recess of the second active pattern 105D. For example, the second high-resistivity bottom epitaxial layer 151D may include at least one of undoped Si, SiB and SiN.

The bottom level LB1′ of the first high-resistivity bottom epitaxial layer 151A may be lower than the bottom level LB4 of the second high-resistivity bottom epitaxial layer 151D. In the example implementation, the second high-resistivity bottom epitaxial layer 151D may have a thickness smaller than that of the first high-resistivity bottom epitaxial layer 151A. For example, the thickness tb of the second high-resistivity bottom epitaxial layer 151D may be 10 nm or lower (e.g., 7 nm or lower). As described above, even when the second high-resistivity bottom epitaxial layer 151D is included, since the second high-resistivity bottom epitaxial layer 151D has a thin thickness, the fourth epitaxial layer 155D may extend further toward the second recess, and similarly to the aforementioned example implementation, the epitaxial patterns 150D may have a fourth epitaxial layer 155D which may be advantageous for a low-resistivity contact having sufficient volume.

As illustrated in FIG. 14, the fourth epitaxial layer 155D may overlap in the horizontal direction (e.g., X-direction) of the lowermost channel pattern 141D among the second channel patterns 140D. Also, the bottom level L3′ of the third epitaxial layer 153D may be positioned at the same level as or lower than a level of an upper surface level of the region of the second active pattern 105D at which the semiconductor stack SL is disposed.

As described above, as for the epitaxial patterns 150D employed in the example implementation, by not providing or forming a high-resistivity bottom epitaxial layer to have a reduced thickness and forming a fourth epitaxial layer 155D for low-resistivity contact to have sufficient volume, the upper contact structure 180B and also the lower contact structure may also be easily formed to have a stable low-resistivity contact.

According to the aforementioned example implementations, a source/drain pattern of a suitable structure may be provided depending on the device type. Particularly, in a long channel element (or a peripheral circuit element), a source/drain pattern of a structure which may be used up to the lowest channel pattern may be implemented, and the source/drain pattern may have a low-resistivity contact with the contact structure.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device, comprising:
a substrate having a first active pattern and a second active pattern;
a first transistor including first channel patterns, stacked and spaced apart from each other, on a first region of the first active pattern, the first channel patterns each having a first channel length, a first gate structure at least partially surrounding the first channel patterns, and first source and drain patterns disposed on opposite sides of the first gate structure, respectively; and
a second transistor including second channel patterns, stacked and spaced apart from each other, on a first region of the second active pattern, the second channel patterns each having a second channel length greater than the first channel length, a second gate structure at least partially surrounding the second channel patterns, and second source and drain patterns disposed on opposite sides of the second gate structure, respectively,
wherein each of the first source and drain patterns comprises a first high-resistivity bottom epitaxial layer, a first epitaxial layer disposed on the first high-resistivity bottom epitaxial layer and connected to a side surface of the first channel patterns, and a second epitaxial layer on the first epitaxial layer,
wherein each of the second source and drain patterns comprises a third epitaxial layer disposed on the second active pattern and connected to a side surface of the second channel patterns, and a fourth epitaxial layer on the third epitaxial layer, and
wherein a bottom level of the first source and drain patterns is lower than a bottom level of the second source and drain patterns, and the fourth epitaxial layer has a portion horizontally overlapping a lowermost channel pattern of the second channel patterns.

2. The semiconductor device of claim 1, wherein a bottom level of the fourth epitaxial layer is lower than a lower surface of the lowermost channel pattern of the second channel patterns.

3. The semiconductor device of claim 2, wherein a bottom level of the third epitaxial layer is lower than an upper surface of the first region of the second active pattern on which the second channel patterns are disposed.

4. The semiconductor device of claim 1, wherein a bottom level of the second epitaxial layer is lower than a lower surface of a lowermost channel pattern of the first channel patterns.

5. The semiconductor device of claim 1, wherein the first high-resistivity bottom epitaxial layer comprises at least one selected from the group including undoped silicon (Si), silicon boron (SiB) and silicon nitride (SIN).

6. The semiconductor device of claim 1, wherein the third epitaxial layer is in contact with the second active pattern.

7. The semiconductor device of claim 1, wherein the second source and drain patterns include a second high-resistivity bottom epitaxial layer between the second active pattern and the third epitaxial layer.

8. The semiconductor device of claim 7, wherein the second high-resistivity bottom epitaxial layer has a thickness smaller than a thickness of the first high-resistivity bottom epitaxial layer.

9. The semiconductor device of claim 8, wherein a thickness of the second high-resistivity bottom epitaxial layer is 10 nm or lower.

10. The semiconductor device of claim 8, wherein a bottom level of the third epitaxial layer is lower than an upper surface of the first region of the second active pattern on which the second channel patterns are disposed.

11. The semiconductor device of claim 7, wherein a bottom level of the second high-resistivity bottom epitaxial layer is 5 nm to 15 nm lower than an upper surface of the first region of the second active pattern on which the second channel patterns are disposed.

12. The semiconductor device of claim 7, further comprising:
a lower contact structure penetrating the substrate and connected to the second source and drain patterns of the second transistor, wherein the lower contact structure is connected to the fourth epitaxial layer.

13. The semiconductor device of claim 1, wherein the second epitaxial layer and the fourth epitaxial layer have concentrations of impurities higher than concentrations of impurities of the first epitaxial layer and the third epitaxial layer, respectively.

14. The semiconductor device of claim 1, wherein the second epitaxial layer and the fourth epitaxial layer have concentrations of germanium higher than concentrations of germanium of the first epitaxial layer and the third epitaxial layer, respectively.

15. The semiconductor device of claim 1,
wherein each of the first active pattern and the second active pattern has a first width, and the substrate further includes a third active pattern having a second width different from the first width, and
wherein the semiconductor device further comprises a third transistor including third channel patterns, stacked and spaced apart from each other, on a first region of the third active pattern, the third channel patterns each having the first channel length, a third gate structure on the third channel patterns, and third source and drain patterns disposed on opposite sides of the third gate structure, respectively.

16. The semiconductor device of claim 15,
wherein each of the third source and drain patterns includes a third high-resistivity bottom epitaxial layer disposed on the third active pattern, a fifth epitaxial layer disposed on the third high-resistivity bottom epitaxial layer and connected to side surfaces of the third channel patterns, and a sixth epitaxial layer on the fifth epitaxial layer, and
wherein a bottom level of the third source and drain patterns is lower than a bottom level of the first source and drain patterns.

17. A semiconductor device, comprising:
a substrate having a first region and a second region;
a first transistor disposed on the first region of the substrate; and
a second transistor disposed on a second region of the substrate,
wherein the first transistor includes:
first channel patterns stacked and spaced apart from each other in a vertical direction on the first region of the substrate and having a first width in a first direction,
a plurality of first gate structures spaced apart from each other in the first direction and at least partially surrounding the first channel patterns in a second direction intersecting the first direction, and
a pair of first source and drain patterns disposed on opposite sides of each of the plurality of first gate structures in the first direction and connected to both side surfaces of the first channel patterns, respectively,
wherein the second transistor includes:
second channel patterns stacked and spaced apart from each other in the vertical direction on the second region of the substrate and having a second width greater than the first width,
a plurality of second gate structures spaced apart from each other in the first direction and at least partially surrounding the second channel patterns in the second direction, and
a pair of second source and drain patterns disposed on opposite sides of each of the plurality of second gate structures in the first direction and connected to both side surfaces of the second channel patterns, respectively,
wherein each of the first source and drain patterns includes a high-resistivity bottom epitaxial layer, a first epitaxial layer on the high-resistivity bottom epitaxial layer, and a second epitaxial layer on the first epitaxial layer,
wherein each of the second source and drain patterns includes a third epitaxial layer and a fourth epitaxial layer on the third epitaxial layer, and
wherein a bottom level of the first source and drain patterns is lower than a bottom level of the second source and drain patterns, and the fourth epitaxial layer has a portion horizontally overlapping a lowermost channel pattern of the second channel patterns.

18. The semiconductor device of claim 17,
wherein a bottom level of the third epitaxial layer is lower than an upper surface of a region of a first active pattern on which the second channel patterns are disposed, and
wherein a bottom level of the fourth epitaxial layer is lower than a lower surface of the lowermost channel pattern of the second channel patterns.

19. The semiconductor device of claim 17,
wherein a width of each of the plurality of second gate structures is greater than a width of each of the plurality of first gate structures, and
wherein a distance between adjacent second gate structures of the plurality of second gate structures is greater than a distance between adjacent first gate structures of the plurality of first gate structures.

20. A semiconductor device, comprising:
a substrate having a first active pattern and a second active pattern, each extending in a first direction;
a first transistor including first channel patterns stacked and spaced apart from each other on a first region of the first active pattern, a first gate structure extending in a second direction intersecting the first direction and at least partially surrounding each of the first channel patterns, and first source and drain patterns disposed on opposite sides of the first gate structure, respectively; and
a circuit element including a semiconductor stack having first semiconductor patterns and second semiconductor patterns alternately stacked on a region of the second active pattern, a second gate structure extending in the second direction and intersecting the semiconductor stack, and epitaxial patterns disposed on both sides of the second gate structure,
wherein a length of the semiconductor stack in the first direction is greater than a length of the first channel patterns in the first direction, and each of the first semiconductor patterns includes a semiconductor material identical to a semiconductor material of the first channel pattern,
wherein each of the first source and drain patterns includes a high-resistivity bottom epitaxial layer, a first epitaxial layer disposed on the high-resistivity bottom epitaxial layer and connected to side surfaces of the first channel patterns, and a second epitaxial layer on the first epitaxial layer,
wherein each of the epitaxial patterns includes a third epitaxial layer disposed on the second active pattern and connected to side surfaces of the first and second semiconductor patterns, and a fourth epitaxial layer on the third epitaxial layer, and
wherein a bottom level of the first source and drain patterns is lower than a bottom level of the epitaxial patterns, and the fourth epitaxial layer has a portion horizontally overlapping a lowermost second semiconductor pattern of the second semiconductor patterns.
